(19) United States
(12) Patent Application Publication
(10) Pub. No.: US 2018/0076038 A1
(43) Pub. Date: Mar. 15, 2018

(54) Method For Producing Two N-Type Buried Layers In An Integrated Circuit

(71) Applicant: Texas Instruments Incorporated, Dallas, TX (US)

(72) Inventors: Tony Phan, Flower Mound, TX (US); Billy Alan Wofford, Sunnyvale, TX (US)

(21) Appl. No.: 15/260,478

(22) Filed: Sep. 9, 2016

(51) Int. Cl. H01L 21/225; H01L 21/266; H01L 29/06; H01L 21/265

(52) U.S. Cl. CPC H01L 21/2253; H01L 21/26513; H01L 29/0684; H01L 21/266

(57) ABSTRACT

A method of fabricating an integrated circuit includes forming a patterned dielectric layer, which includes a first pattern of openings, over a substrate and implanting a first n-type dopant into the substrate through the patterned dielectric layer to form a first doped region. The method continues with forming a patterned photoresist layer overlying the patterned dielectric layer, which includes a second pattern of openings and implanting a second n-type dopant into the substrate through the patterned photoresist layer and patterned dielectric layer to form a second doped region. The patterned photoresist layer and patterned dielectric layer are removed. An epitaxial layer is grown on the substrate and the first doped region and second doped region are driven into said epitaxial layer to form respective first and second n-type buried layers, then active devices are formed in the epitaxial layer.

### FIELD OF THE DISCLOSURE

Disclosed embodiments relate generally to the field of manufacturing semiconductor devices. More particularly, and not by way of any limitation, the present disclosure is directed to a method for producing two n-type buried layers in an integrated circuit.

### BACKGROUND

Semiconductor manufacturing requires highly controlled processing in an ultra-clean environment and can be a very expensive process. Manufacturers are constantly looking for ways to improve the flow, shorten the processing time and/or lower the costs of production for a given process, such as implanting two different buried layers on a single chip.

### SUMMARY

Disclosed embodiments provide a method of producing dual buried layers in a semiconductor chip that eliminates a number of steps from a prior process to accomplish the same result. The disclosed embodiments decrease the time necessary to produce the end product and consequently lowers the cost of production. Other advantages are discussed in the specification.

In one aspect, an embodiment of a method of forming two n-type regions in a substrate is disclosed. The method includes implanting a first n-type dopant into the substrate through openings in a dielectric layer that is patterned for a first region; forming a first photoresist layer overlying the dielectric layer, the first photoresist layer being patterned for a second region; and implanting a second n-type dopant into said substrate through openings in said first photoresist layer.

### BRIEF DESCRIPTION OF THE DRAWINGS

Embodiments of the present disclosure are illustrated by way of example, and not by way of limitation, in the figures of the accompanying drawings in which like references indicate similar elements. It should be noted that different references to “an” or “one” embodiment in this disclosure are not necessarily to the same embodiment, and such references may mean at least one. Further, when a particular feature, structure, or characteristic is described in connection with an embodiment, it is submitted that it is within the knowledge of one skilled in the art to effect such feature, structure, or characteristic in connection with other embodiments whether or not explicitly described.

The accompanying drawings are incorporated into and form a part of the specification to illustrate one or more exemplary embodiments of the present disclosure. Various advantages and features of the disclosure will be understood from the following Detailed Description taken in connection with the appended claims and with reference to the attached drawing figures in which:

FIGS. 1A-H depict various stages in the process of forming n-type buried regions in an integrated circuit chip according to an embodiment of the disclosure;

FIG. 2 depicts a graphic comparison of the simulated concentration of phosphorus in the deep n-type buried layer using the prior art process and using the disclosed embodiment;

FIG. 3A depicts a flowchart of a method of fabricating an integrated circuit;

FIG. 3B depicts a flowchart of a method of forming two n-type buried regions in an integrated circuit chip;

FIG. 3C depicts a flowchart of a method of forming two n-type regions in an integrated circuit chip according to an embodiment of the disclosure; and

FIGS. 4A-D depict various stages in the process of forming two buried layers in a semiconductor substrate according to the prior art.

### DETAILED DESCRIPTION OF THE DRAWINGS

Specific embodiments of the invention will now be described in detail with reference to the accompanying figures. In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

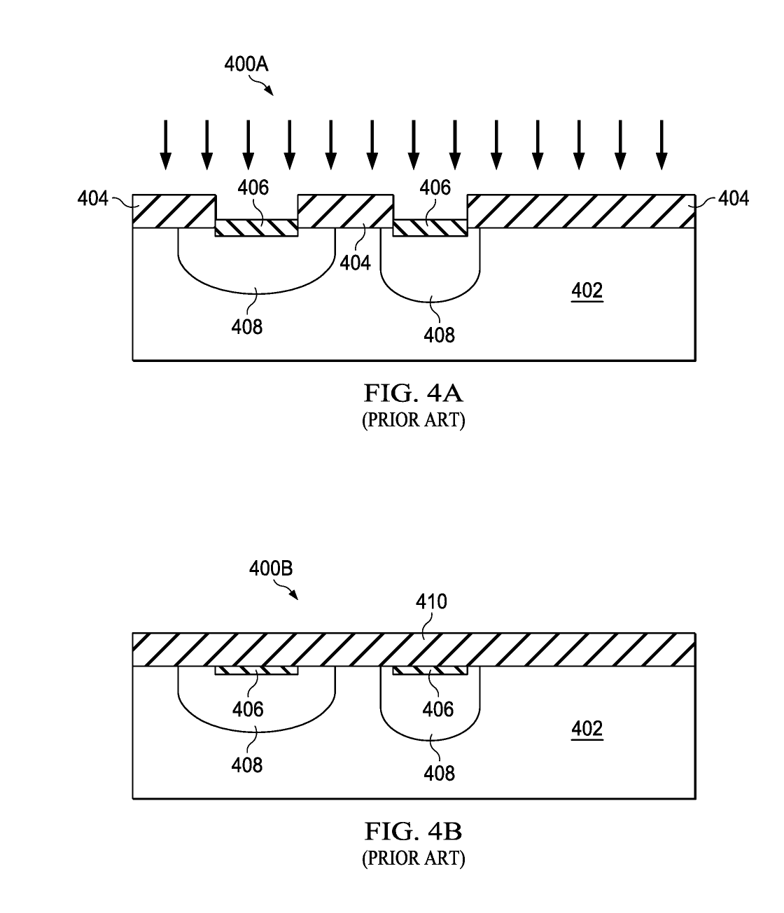

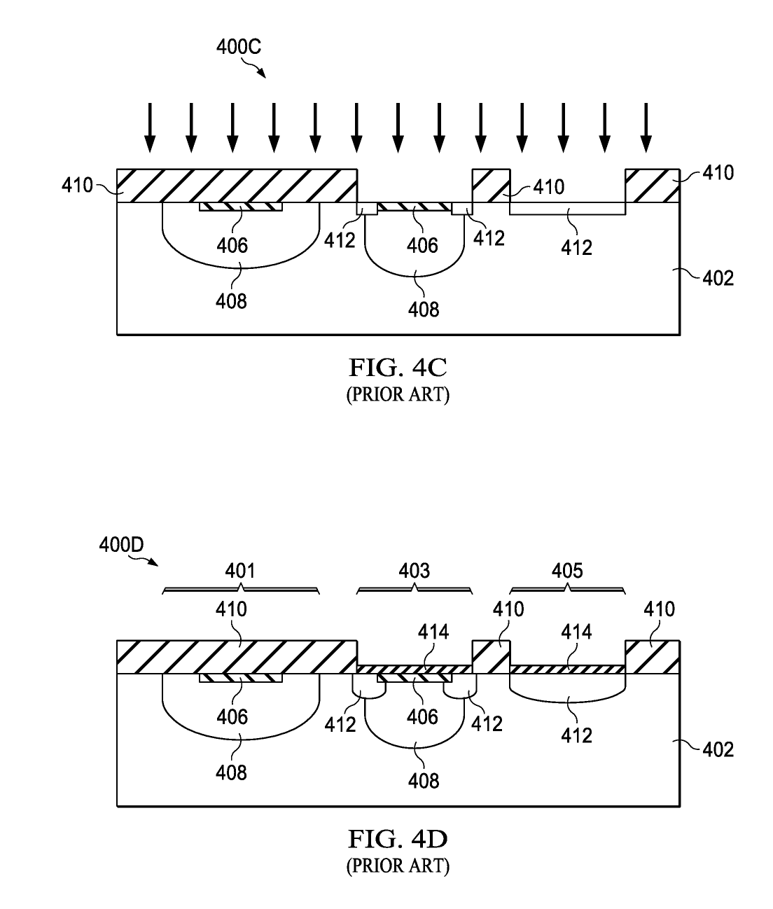

Turning first to FIGS. 4A-D, a prior-art process of forming dual n-type buried layers in a semiconductor substrate is shown. In the process shown, an n-type buried layer (NBL) region 405 is formed on the right side of the figure, a deep n-type buried layer (DNBL) region 401 is formed on the left side and a region with overlapping sections of both implants 403 is shown in the middle of the figure. It will be understood that not all of these regions are necessarily included in a single layout; rather these are all shown for the purpose of illustration. The process begins with a semiconductor substrate 402, which in one embodiment is a silicon wafer. At the point shown as 400A, a first oxidation layer 404, i.e., silicon dioxide, has been grown on the top surface of substrate 402. Typically, this oxidation layer is 7500 Å thick in order that the oxidation layer can act as a hardmask for the implantation process. Oxidation layer 404 has been patterned using a photoresist (not specifically shown), which has then been removed. A thin pad oxide layer 406, e.g. 200A thick, is grown to protect the surface of the substrate during the implantation process. In the example process, phosphorus (P) is implanted into substrate 402 at a dosage of 1.5×10¹³/cm² and an energy level of 150 KV. This process is then followed by a DNBL drive to form DNBL 408. The DNBL drive is generally performed at 1200° C. for 30 minutes.

After the DNBL drive is completed, oxidation layer 404 is stripped off and a second oxidation layer 410, also 7500A thick, is grown on substrate 402. This stage of the process is shown as 400B. At the stage shown at stage 400C, oxidation layer 410 has been patterned using a photoresist layer (not specifically shown), which is then removed. A second implantation is performed through the patterned opening in oxidation layer 410 to form NBL implant 412. In at least one embodiment, the second implantation process implants antimony at a dosage of 2×10¹⁵/cm² at an energy of 60 KV.

Once the implantation is completed, a diffusion-under-field (DUF) drive is performed to drive the two implants further into the substrate, creating the regions shown as 400D. As the DUF drive is performed, pad oxide 414 grows on the exposed silicon overlying NBL implant 412. This completes the prior process of forming the dual buried layers. While the process illustrated in FIGS. 4A-D works well, Applicant has determined that by modifying the process, the same doping profiles can be reproduced using several days less time and thus saving on the costs of manufacturing chips which use the disclosed process.

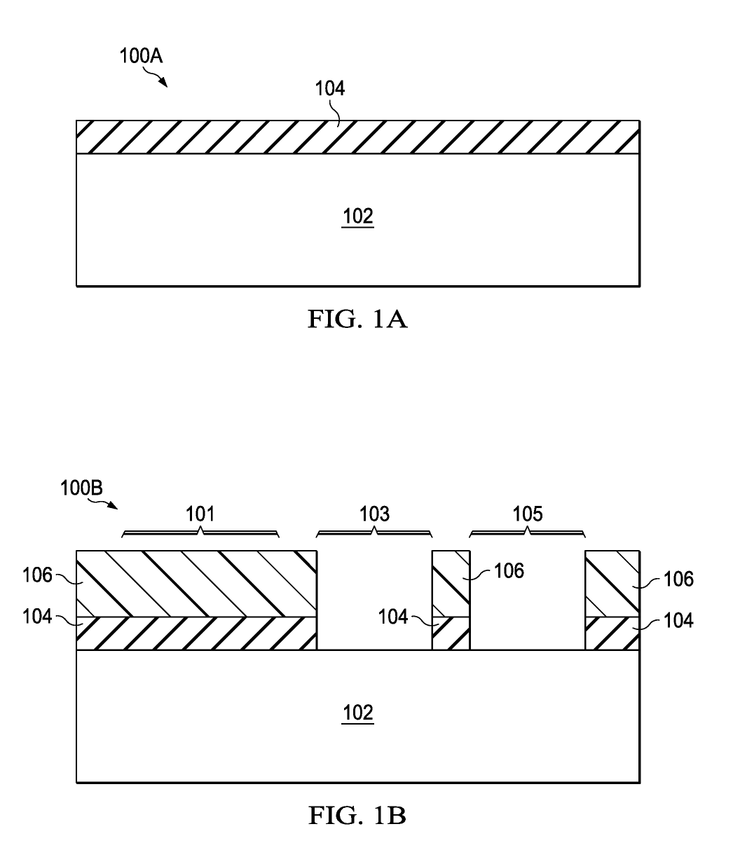

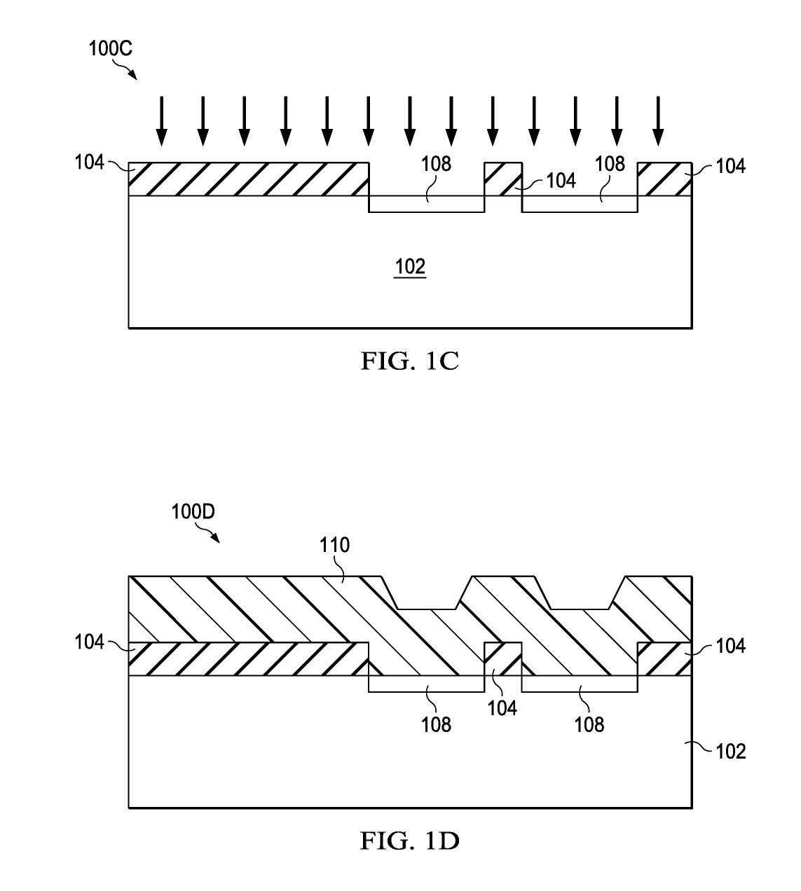

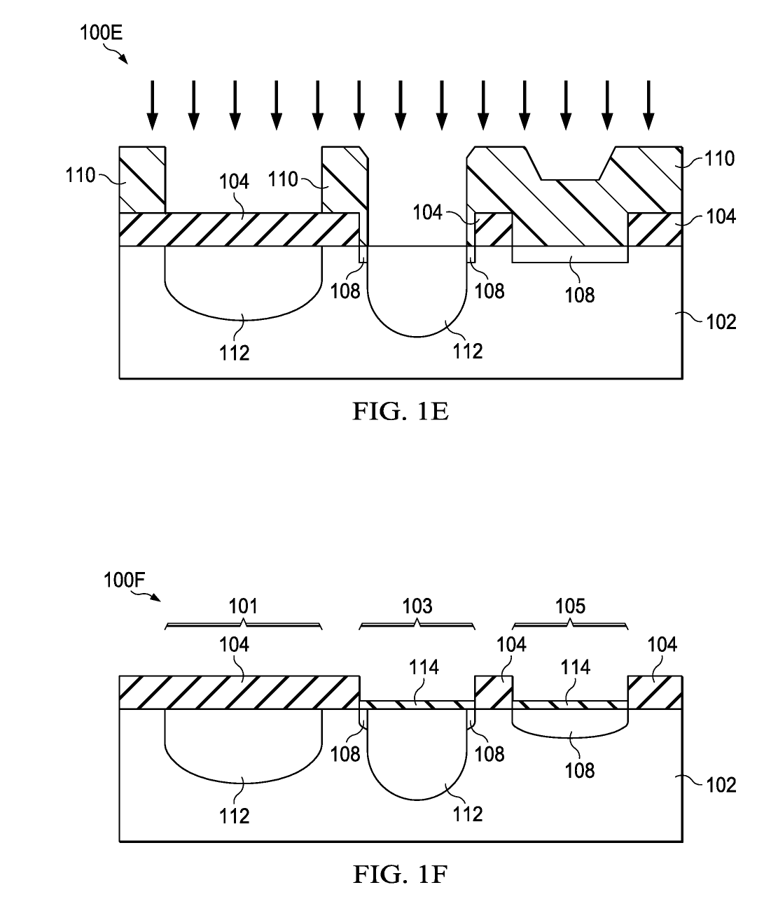

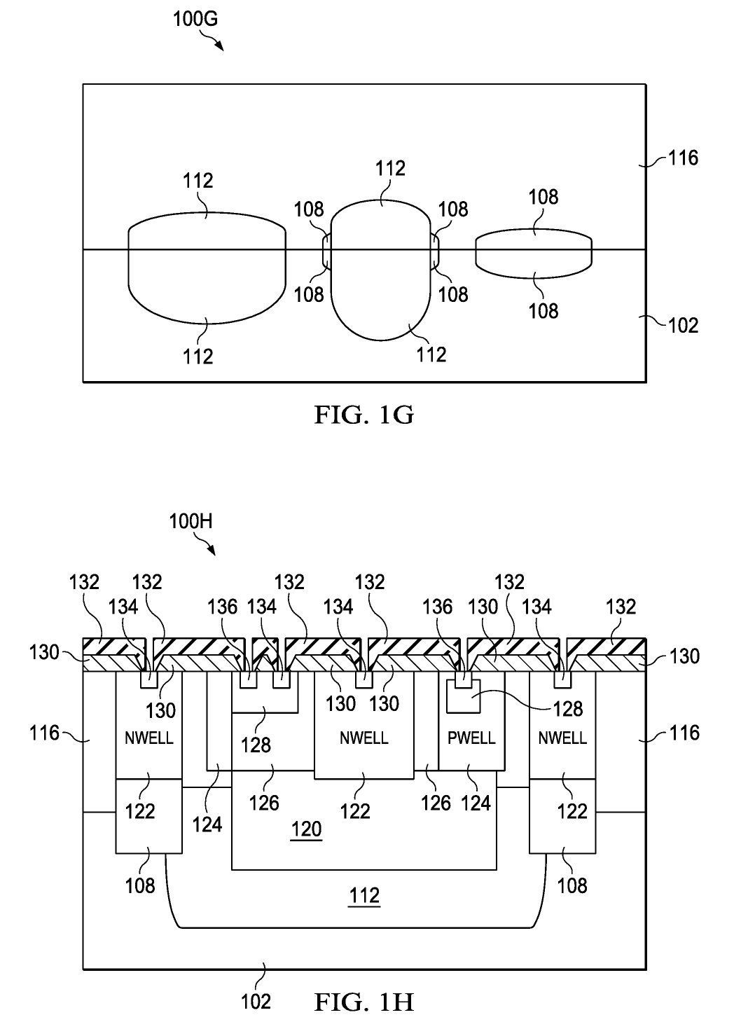

The modified process will now be explained with reference to FIGS. 1A-F. This process is described in terms of DNBL 101, NBL 105 and overlapping NBL+DNBL region 103, as were shown in the prior art, but it will be understood that the disclosed process can be used with implanting two n-type dopants for other types of regions. At stage 100A, oxidation layer 104 has been grown on the surface of substrate 102. In at least one embodiment, oxidation layer 104 again has a thickness of 7500 Å. At stage 100B, photoresist 106 has been deposited over oxidation layer 104 and a pattern that was created in photoresist 106 has been etched into oxidation layer 104 to expose the substrate in areas where an n-type buried layer is desired. In at least one embodiment, photoresist 106 is 1 micron thick.

As seen in 100C, photoresist 106 is removed prior to implanting antimony in a blanket implant process to create NBL 108. In one embodiment, the implantation process to create NBL 108 is performed at 60 KV and implants antimony at a dosage of 2×10¹⁵/cm². The DUF drive that previously followed the implantation of NBL 108 is not performed at this point, although it will be performed at a later time. As seen in stage 100D, a new oxidation layer is not created between the two implantation processes; rather photoresist layer 110 simply covers both oxidation layer 104 and exposed regions of substrate 102. Since photoresist 110 is a conformal layer, the topography of the photoresist 110 is not entirely smooth.

In the disclosed process, the DNBL implantation takes place through oxide layer 104 and thus requires higher energy to perform. In one embodiment, the thickness of photoresist 110 is increased to 1.5 microns. As seen in 100E, photoresist 110 has been patterned, although the underlying oxidation layer 104 has not been disturbed. The substrate is, of course, already exposed in the region where the DNBL and NBL overlap. A close examination reveals that the opening through which DNBL 112 will be formed is somewhat larger than the opening used in the prior art process; this adjustment compensates for the fact that no DNBL drive is performed in the disclosed process. One advantage of the disclosed process is that whenever a thermal process is performed on the substrate, e.g., the prior art re-growing of 7500 Å of oxide, outgassing of the dopant can occur through exposed regions and may contaminate other regions. Since in the disclosed embodiments, no thick growth of oxide is performed after the implant, little or no outgassing or cross contamination by the phosphorus occurs.

In one embodiment, the blanket implantation of phosphorus is a chain implant, with one segment implanting 1.0×10¹³/cm² at 90 Kev and a second segment implanting 1.5×10¹³/cm² at 1.3 MeV. The first, low energy implant will be blocked by the thick oxide layer over the DNBL region 101, but will penetrate in the overlapping region 103. The second, high energy implant will penetrate the thick oxide overlying region 101 and will penetrate deeply into the substrate in region 103. In the steps illustrated in 100F, photoresist 110 was ashed and substrate 102 was subjected to the DUF drive that was not previously performed. Note that the DUF drive will enlarge both NBL 108 and DNBL 112 by driving each further into the substrate. During this process, a thin layer of silicon dioxide 114 is also formed.

This completes the process of implanting two n-type dopants into a substrate, although this process will be understood to be part of a larger process that includes forming two n-type buried layers and forming the rest of the circuit, e.g., active devices. As seen in 100G, the oxidation layers and any other dielectric remaining on the surface of substrate 102 has been removed and an epitaxial layer 116 has been grown. As the epitaxial layer is grown, the buried implants are driven into epitaxial layer 116 to form an n-type buried layer 108 and a deep n-type buried layer 112. Depending on the specific circuit in which the disclosed dual n-type layers is being used, further processing can take many forms.

FIG. 1H illustrates an example of an integrated circuit 100H that utilizes the disclosed dual n-type buried layers. This example is a cross section of a portion of a power NMOS device and depicts active devices that have been formed in the epitaxial layer. Integrated circuit 100H includes deep n-type buried layer (DNBL) 112 and n-type buried layer (NBL) 108, which have been implanted into substrate 102 and driven into epitaxial layer 116 as this layer was grown. The circuit also includes a deep p-type buried layer (DNBL) 120 and both n-type wells 122 and p-type well 124, as well as high-voltage p-well implant (HVPW) 126_and n-channel voltage adjust implant (VTN) 128. N-type contact areas 134 and P-type contact areas 136 are also shown. Of course, other specific active devices can also be formed over the disclosed buried layers. Oxide layer 130 and an inter-level dielectric 132 complete this circuit.

The process has been disclosed for two buried layers grown in the substrate of a silicon wafer. However, other semiconductor materials, such as germanium and selenium, can also be used in conjunction with the disclosed method. Further, this method can also be used after an epitaxial layer has been formed. Therefore, for the purposes of this application, reference to actions performed on a substrate can also be interpreted to include actions performed on an epitaxial layer. Additionally, when the disclosed implantations are performed after the epitaxial layer is formed, regions other than buried layers can be created using the disclosed process.

Applicant notes that it is possible to utilize the disclosed process, while reversing the order of the implantations, i.e., the process can implant dopants for the DNBL through openings in a photoresist layer prior to implanting dopants for the NBL through openings in the dielectric layer. However, it is important that patterns are aligned to each other so that the relationship between different regions is maintained. Since the dielectric layer is not itself patterned when implanting the DNBL region, performing the DNBL implant first would require additional actions to form alignment marks that can be used when patterning the NBL layer. By implanting NBL first, alignment marks can be formed in the dielectric layer when the pattern etch for the NBL layer is performed, such that no additional actions are needed.

Table 1 below shows a comparison of the actions performed in the prior art method and those performed in the disclosed procedures:

TABLE 1

| PRIOR ART | DISCLOSED PROCESS |
|---|---|
| 1ST OXIDATION | 1ST OXIDATION (7500A) |
| DNBL PATTERN | Moved |
| DNBL ETCH | Removed |
| DNBL ETCH CLEAN | Removed |
| DNBL PAD OX | Removed |
| DNBL IMPLANT | Moved |
| DNBL DRIVE | Removed |
| 2ND OXIDATION | Removed |
| N+ BL PATTERN | N+ BL PATTERN |
| (Aligned to DNBL) | |
| N+ BL ETCH | N+ BL ETCH |
| N+ BL CLEAN | N+ BL CLEAN |
| NBL IMPLANT | NBL IMPLANT |
| | DNBL PATTERN (Aligned to NBL; Upsized |
| | opening compensates for no DNBL Drive) |
| | DNBL IMPLANT (Chain implant; at least one |
| | segment is a high energy implant >1 MeV to |
| | penetrate 7500A Oxide) |
| DUF DRIVE | DUF DRIVE |

It can be seen in the comparison shown by this table that the changes made by the disclosed process eliminate the need for a number of actions, such as etching the oxide prior to implanting the DNBL and cleaning up after the etch is completed. There is also no need to grow a pad oxide, as a much thicker oxide already exists on top of the substrate where the DNBL is to be implanted. Additionally, the DNBL drive is removed from the process. Finally, since the first oxidation layer is not removed in the second process, there is no need to grow a second oxidation layer in preparation for the DNBL implantation. In one embodiment, the time saved in removing all of these actions amounts to approximately three days, which over the lifetime of the process can potentially save millions of dollars.

Although the process is described herein using phosphorus for the DNBL and antimony for the NBL, other n-type dopants can be used. The most commonly used n-type dopants are phosphorus, arsenic and antimony, which have atomic mass units (AMU) of 31, 75 and 121 respectively. Any of these dopants or other less commonly used n-type dopants can be used for the NBL layer, which is implanted directly into the substrate. Implanting dopants through the dielectric layer requires using high implant energy, with higher AMU species requiring higher implant energies to penetrate through the dielectric. Arsenic can be implanted in the example DNBL through the dielectric; in one embodiment using arsenic, the oxidation layer is reduced to below 5000 Å. Antimony would not generally be used to implant through the oxidation layer due to its large AMU. All of these variations fall within the scope of this disclosure.

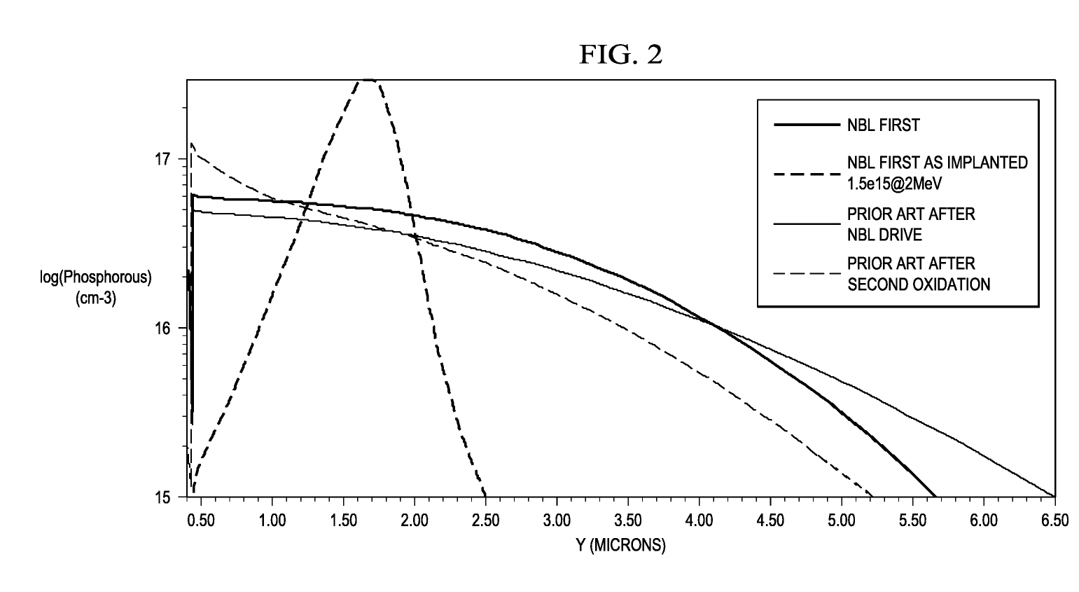

FIG. 2 illustrates a comparison between the simulated concentration of phosphorus for both the prior art process and for the disclosed embodiment. The dotted lines show the prior art after the second oxidation process and also show the present embodiment as implanted, while the solid lines show both the prior art and the present embodiment after respective NBL drives. It can be seen that the distribution of the phosphorus as implanted in the new process (labeled NBL First) is concentrated at depths between 0.5 μm and 2.5 μm, with a peak at 1.7 μm, while the prior art process is heaviest near the surface of the chip and gradually lessens to around 5.25 μm. However, the NBL drive causes the phosphorus to be redistributed through the substrate so that the two profiles after the NBL drive can be seen to be quite similar.

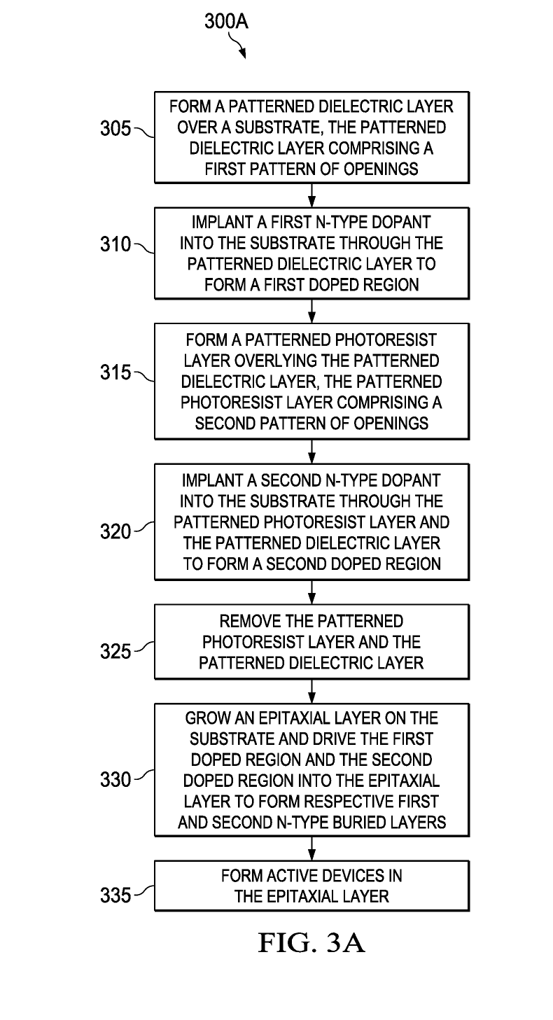

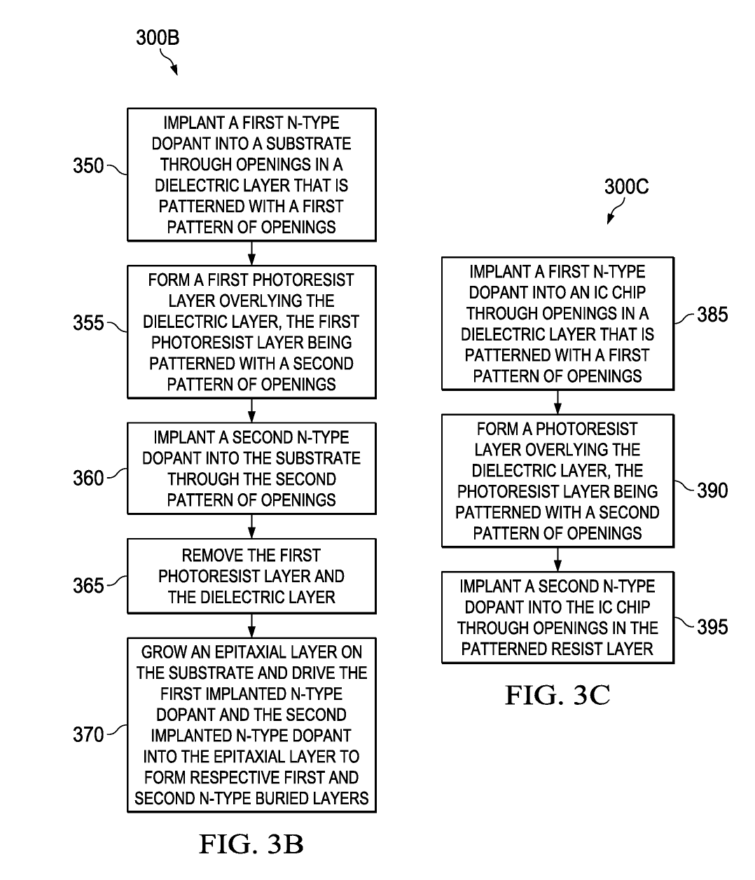

FIGS. 3A-C each disclose a method that includes implanting two n-type dopants into an IC chip as has been disclosed, each including different levels of additional processing on the chip. FIG. 3A depicts a method 300A of fabricating an integrated circuit. As expressed in flowchart 300A, the method begins with forming (305) a patterned dielectric layer over a substrate, where the patterned dielectric layer includes a first pattern of openings. In one embodiment, the substrate is a silicon wafer and the dielectric layer is silicon dioxide. This can include forming the dielectric layer, patterning the dielectric and performing any clean-up necessary to present a clean, prepared surface for implantation. The method continues with implanting (310) a first n-type dopant into the substrate through the patterned dielectric layer to form a first doped region. Next a patterned photoresist layer is formed (315) overlying the patterned dielectric layer, where the patterned photoresist layer includes a second pattern of openings, followed by implanting (320) a second n-type dopant into the substrate through the patterned photoresist layer to form a second doped region. The method removes (325) the patterned photoresist layer and the patterned dielectric layer, then grows (330) an epitaxial layer on the substrate and drives the first doped region and the second doped region into the epitaxial layer to form respective first and second n-type buried layers. Finally, the method forms (335) active devices in the epitaxial layer.

FIG. 3B depicts a method 300B of forming two n-type buried regions in an integrated circuit chip. This method implants (350) a first n-type dopant into a substrate through openings in a dielectric layer that is patterned with a first pattern of openings and forms (355) a first photoresist layer overlying the dielectric layer, where the first photoresist layer is patterned with a second pattern of openings. The method continues to implant (360) a second n-type dopant into the substrate through the second pattern of openings, then removes (365) the first photoresist layer and the dielectric layer, and finishes by growing (370) an epitaxial layer on the substrate and driving the first implanted n-type dopant and the second implanted n-type dopant into the epitaxial layer to form respective first and second n-type buried layers.

FIG. 3C depicts a third method (300C) of forming two n-type regions in an integrated circuit chip. This method implants (385) a first n-type dopant into the IC chip through openings in a dielectric layer that is patterned with a first pattern of openings, forms (390) a photoresist layer overlying the dielectric layer, where the photoresist layer is patterned with a second pattern of openings and implants (395) a second n-type dopant into the IC chip through openings in the photoresist layer.

Although various embodiments have been shown and described in detail, the claims are not limited to any particular embodiment or example. None of the above Detailed Description should be read as implying that any particular component, element, step, act, or function is essential such that it must be included in the scope of the claims. Reference to an element in the singular is not intended to mean “one and only one” unless explicitly so stated, but rather “one or more.” All structural and functional equivalents to the elements of the above-described embodiments that are known to those of ordinary skill in the art are expressly incorporated herein by reference and are intended to be encompassed by the present claims. Accordingly, those skilled in the art will recognize that the exemplary embodiments described herein can be practiced with various modifications and alterations within the spirit and scope of the claims appended below.

1. A method of fabricating an integrated circuit comprising:
forming a patterned dielectric layer over a substrate and removing a patterned photoresist layer used to form said patterned dielectric layer, said patterned dielectric layer comprising a first pattern of openings that includes a first opening;
implanting a first n-type dopant into said substrate at a first location through said first opening in said patterned dielectric layer to form a first doped region;
forming a patterned photoresist layer overlying said patterned dielectric layer, said patterned photoresist layer comprising a second pattern of openings that includes a second opening;
implanting a second n-type dopant into said substrate at a second location through said second opening in said patterned photoresist layer and a portion of said patterned dielectric layer exposed through said second opening to form a second doped region, wherein said second location remains masked by said exposed portion of said patterned dielectric layer during said implanting of said second n-type dopant;
after implanting said second n-type dopant, removing said patterned photoresist layer and said patterned dielectric layer;
growing an epitaxial layer on said substrate and driving said first doped region and said second doped region into said epitaxial layer to form respective first and second n-type buried layers; and
forming active devices in said epitaxial layer.

2. The method of fabricating an integrated circuit as recited in claim 1 further comprising performing a thermal drive operation only after implanting both said first n-type dopant and said second n-type dopant.

3. The method of fabricating an integrated circuit as recited in claim 2 wherein implanting said second n-type dopant comprises using a MeV ion implanter to form said second doped region.

4. The method of fabricating an integrated circuit as recited in claim 2 wherein said patterned dielectric layer comprises approximately 7500 Å of silicon dioxide.

5. The method of fabricating an integrated circuit as recited in claim 2 wherein said patterned dielectric layer is approximately 5000 Å of silicon dioxide.

6. The method of fabricating an integrated circuit as recited in claim 2 wherein said first n-type dopant comprises antimony and said second n-type dopant comprises phosphorus.

7. The method of fabricating an integrated circuit as recited in claim 2 wherein at least a portion of said first pattern of openings and said second pattern of openings overlap.

8. The method of fabricating an integrated circuit as recited in claim 2 wherein no portion of said first pattern of openings and said second pattern of openings overlap.

9. A method of forming two n-type buried regions in an integrated circuit chip (IC), the method comprising:
implanting a first n-type dopant into a substrate at a first location through a first opening in a dielectric layer overlying said substrate, said dielectric layer being patterned with a first pattern of openings that includes said first opening and a patterned photoresist layer used to form said patterned dielectric layer being removed after said patterning of said dielectric layer;
forming a first photoresist layer overlying said dielectric layer, said first photoresist layer being patterned with a second pattern of openings that includes a second opening;
implanting, through said second opening in said first photoresist layer, a second n-type dopant into said substrate at a second location covered by said dielectric layer during said implanting of said second n-type dopant;
removing said first photoresist layer and said dielectric layer after said implanting of said second n-type dopant; and
growing an epitaxial layer on said substrate and driving said first implanted n-type dopant and said second implanted n-type dopant into said epitaxial layer to form respective first and second n-type buried layers.

10. The method of forming two n-type buried regions in said IC chip as recited in claim 9 wherein implanting said second n-type dopant comprises using a MeV ion implanter.

11. The method of forming two n-type buried regions in said IC chip as recited in claim 10 further comprising performing a thermal drive operation only after implanting both said first n-type dopant and said second n-type dopant.

12. The method of forming two n-type buried regions in said IC chip as recited in claim 11 further comprising:
depositing said dielectric layer;
patterning said dielectric layer using a second photoresist layer and said first pattern of openings; and
removing said second photoresist layer.

13. The method of forming two n-type buried regions in said IC chip as recited in claim 12 wherein said patterned dielectric layer comprises approximately 7500 Å of silicon dioxide.

14. The method of forming two n-type buried regions in said IC chip as recited in claim 12 wherein said patterned dielectric layer is approximately 5000 Å of silicon dioxide.

15. The method of forming two n-type buried regions in said IC chip as recited in claim 8 wherein said first n-type dopant comprises antimony and said second n-type dopant comprises arsenic.

16. The method of forming two n-type buried regions in said IC chip as recited in claim 11 wherein at least a portion of said first pattern of openings and said second pattern of openings overlap.

17. The method of forming two n-type buried regions in said IC chip as recited in claim 11 wherein no portion of said first pattern of openings and said second pattern of openings overlap.

18. A method of forming two n-type regions in an integrated circuit (IC) chip, the method comprising:
implanting a first n-type dopant into said IC chip through openings in a dielectric layer that is patterned with a first pattern of openings and a patterned photoresist used to form said patterned dielectric layer being removed;
forming a photoresist layer that covers said dielectric layer;
patterning said photoresist layer with a second pattern of openings that includes at least one opening that exposes a portion of said dielectric layer not having an opening; and
implanting a second n-type dopant into said IC chip through said at least one opening in said photoresist layer and said exposed portion of said dielectric layer.

19. The method as recited in claim 18, wherein, after forming said photoresist layer and before implanting said second n-type dopant, no portion of said dielectric layer covered by said photoresist layer prior to said patterning of said photoresist layer is removed.
